(19) United States
(12) Patent Application Publication
(10) Pub. No.: US 2026/0343735 A1
(43) Pub. Date: Oct. 29, 2026

(54) WIRING CIRCUIT BOARD

(71) Applicant: NITTO DENKO CORPORATION, Osaka (JP)

(72) Inventors: Shoei TETSUKAWA, Osaka (JP); Takahiro IKEDA, Osaka (JP); Takaya KOUCHI, Osaka (JP); Shusaku SHIBATA, Osaka (JP)

(73) Assignee: NITTO DENKO CORPORATION, Osaka (JP)

(21) Appl. No.: 19/650,036

(22) Filed: Apr. 16, 2026

(30) Foreign Application Priority Data
Apr. 25, 2025 (JP) 2025-073351

(51) Int. Cl. H05K 1/02

(52) U.S. Cl. CPC H05K 1/0298

(57) ABSTRACT

A wiring circuit board includes a first insulating layer, a first circuit pattern, a metal support layer insulated from the first circuit pattern by the first insulating layer, a second circuit pattern independent from the first circuit pattern. Furthermore, the second circuit pattern includes a first terminal. The first terminal includes a metal layer continuous with the metal support layer, a terminal metal layer disposed at one side of the metal layer in the thickness direction, a terminal covering layer made of metal and covering the terminal metal layer, and an adhesion layer disposed between the metal layer and the terminal covering layer in the thickness direction.

### CROSS-REFERENCE TO RELATED APPLICATION

The present application claims priority from Japanese Patent Application No. 2025-073351 filed on Apr. 25, 2025, the content of which is hereby incorporated by reference into this application.

### TECHNICAL FIELD

The present disclosure relates to a wiring circuit board.

### BACKGROUND ART

Conventionally, there has been a known wiring circuit board including a metal support layer, a base insulating layer disposed at one side of the metal support layer, and a conductor layer disposed at one side of the base insulating layer (for example, see Patent Document 1 below).

### Citation List

### Patent Document

Patent Document 1: Japanese Unexamined Patent Publication No. 2020-188189

### SUMMARY OF THE INVENTION

### PROBLEM TO BE SOLVED BY THE INVENTION

There are considerations of further improvement in the degree of freedom of circuit design in the wiring circuit board as described in Patent Document 1.

The present disclosure provides a wiring circuit board capable of improving the degree of freedom of circuit design.

### MEANS FOR SOLVING THE PROBLEM

The present invention [1] includes a wiring circuit board including: a first insulating layer; a first circuit pattern disposed at one side of the first insulating layer in a thickness direction of the first insulating layer; a metal support layer disposed at an opposite side to the first circuit pattern with respect to the first insulating layer in the thickness direction, insulated from the first circuit pattern by the first insulating layer, and supporting the first circuit pattern and the first insulating layer; and a second circuit pattern independent from the first circuit pattern, wherein the second circuit pattern includes a first terminal, wherein the first terminal includes: a metal layer continuous with the metal support layer; a terminal metal layer disposed at one side of the metal layer in the thickness direction; a terminal covering layer made of metal and covering the terminal metal layer; and an adhesion layer disposed between the metal layer and the terminal covering layer in the thickness direction.

According to such a configuration, the first terminal of the second circuit pattern has a metal layer continuous with the metal support layer.

Therefore, by utilizing a metal support layer that supports the first circuit pattern, it is possible to design a second circuit pattern independent from the first circuit pattern.

As a result, it is possible to improve the degree of freedom of the circuit design.

Further, the metal layer of the first terminal is continuous with the metal support layer. Thus, as compared with the case of forming the second circuit pattern by separating a part of the metal support layer from the metal support layer, it is possible to suppress the reduction in the stiffness of the metal support layer due to the formation of the second circuit pattern.

Furthermore, the terminal covering layer covers the terminal metal layer, and the terminal metal layer can be protected by the terminal covering layer.

In addition, according to such a configuration, the first terminal includes an adhesion layer disposed between the metal layer and the terminal covering layer.

Thus, it is possible to suppress the release of the terminal covering layer.

The present invention [2] includes the wiring circuit board described in the above-described [1], wherein the adhesion layer is disposed in a peripheral edge portion of the terminal metal layer.

According to such a configuration, it is possible to suppress the release of the terminal covering layer in the peripheral edge portion of the terminal metal layer.

The present invention [3] includes the wiring circuit board described in the above-described [1] or [2], wherein in the thickness direction, the adhesion layer is disposed between the metal layer and the terminal metal layer, wherein the adhesion layer includes an opening portion, and wherein the terminal metal layer is electrically connected to the metal layer through the opening portion.

The present invention [4] includes the wiring circuit board described in any one of the above-described [1] to [3], further including a conductor layer disposed between the first insulating layer and the metal support layer in the thickness direction.

According to such a configuration, it is possible to improve the electrical properties of the wiring circuit board.

The present invention [5] includes the wiring circuit board described in any one of the above-described [1] to [4], wherein the first terminal further includes a terminal conductor layer disposed between the metal layer and the terminal metal layer in the thickness direction.

According to such a configuration, it is possible to improve the conductive performance of the second circuit pattern.

The present invention [6] includes the wiring circuit board described in the above-described [5], wherein the terminal conductor layer is continuous with the conductor layer.

According to such a configuration, by utilizing the conductor layer, it is possible to design a second circuit pattern independent from the first circuit pattern.

As a result, it is possible to improve the degree of freedom of the circuit design.

The present invention [7] includes the wiring circuit board described in the above-described [5] or [6], wherein in the thickness direction, the adhesion layer is disposed between the terminal conductor layer and the terminal metal layer, wherein the adhesion layer includes an opening portion, and wherein the terminal metal layer is electrically connected to the terminal conductor layer through the opening portion.

### EFFECTS OF THE INVENTION

According to the wiring circuit board of the present disclosure, it is possible to improve the degree of freedom of the circuit design.

### BRIEF DESCRIPTION OF THE DRAWINGS

FIG. 1 is a plan view of one embodiment of the wiring circuit board of the present disclosure. In FIG. 1, the second insulating layer and the terminal covering layer are omitted.

FIG. 2A is a cross-sectional view of the wiring circuit board shown in FIG. 1, taken along line A-A. FIG. 2 B is a cross-sectional view of the wiring circuit board shown in FIG. 1, taken along line B-B.

FIGS. 3A - 3C are process diagrams showing the steps of producing the wiring circuit board shown in FIGS. 1, FIG. 3A shows the conductor layer forming step, FIG. 3B shows the first insulating layer forming step, and FIG. 3C shows the conductor pattern forming step.

FIGS. 4A-4C are process diagrams showing the steps of producing the wiring circuit board, following FIGS. 3C, FIG. 4A shows the second insulating layer forming step, FIG. 4B shows the outer shape trimming step, and FIG. 4C shows the cover layer forming step.

FIGS. 5A and 5B show a modified example (1) of the wiring circuit board, FIG. 5A is a cross-sectional view corresponding to the A-A cross-sectional view of FIG. 2A, and FIG. 5B is a cross-sectional view corresponding to the B-B cross-sectional view of FIG. 2B.

FIGS. 6A and 6B show a modified example (2) of the wiring circuit board, FIG. 6A is a cross-sectional view corresponding to the A-A cross-sectional view of FIGS. 2A, FIG. 6B is a cross-sectional view corresponding to the B-B cross-sectional view of FIG. 2B.

FIGS. 7A and 7B show a modified example (3) of the wiring circuit board, FIG. 7A is a cross-sectional view corresponding to the A-A cross-sectional view of FIGS. 2A, FIG. 7B is a cross-sectional view corresponding to the B-B cross-sectional view of FIG. 2B.

FIGS. 8A and 8B are cross-sectional views of a modified example (4) of the wiring circuit board.

FIG. 9 is a plan view of a modified example (5) of the wiring circuit board.

FIG. 10 is a plan view of a modified example (6) of the wiring circuit board.

FIGS. 11A and 11B show a modified example (7) of the wiring circuit board, FIG. 11A is a plan view of the modified example (7) of the wiring circuit board, and FIG. 11B is a cross-sectional view of the wiring circuit board shown in FIG. 11A, taken along line C-C.

### DESCRIPTION OF THE EMBODIMENT

### 1. Wiring Circuit Board

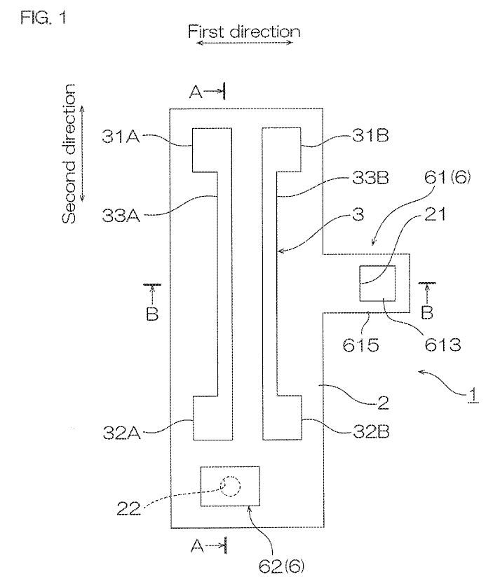

As shown in FIG. 1, in the present embodiment, a wiring circuit board 1 extends in a first direction and a second direction. The first direction is a direction in which a plurality of terminals 31A and 31B are aligned. The terminals 31A and 31B are described later. The second direction is perpendicular to the first direction. The shape of the wiring circuit board 1 is not limited to the present embodiment.

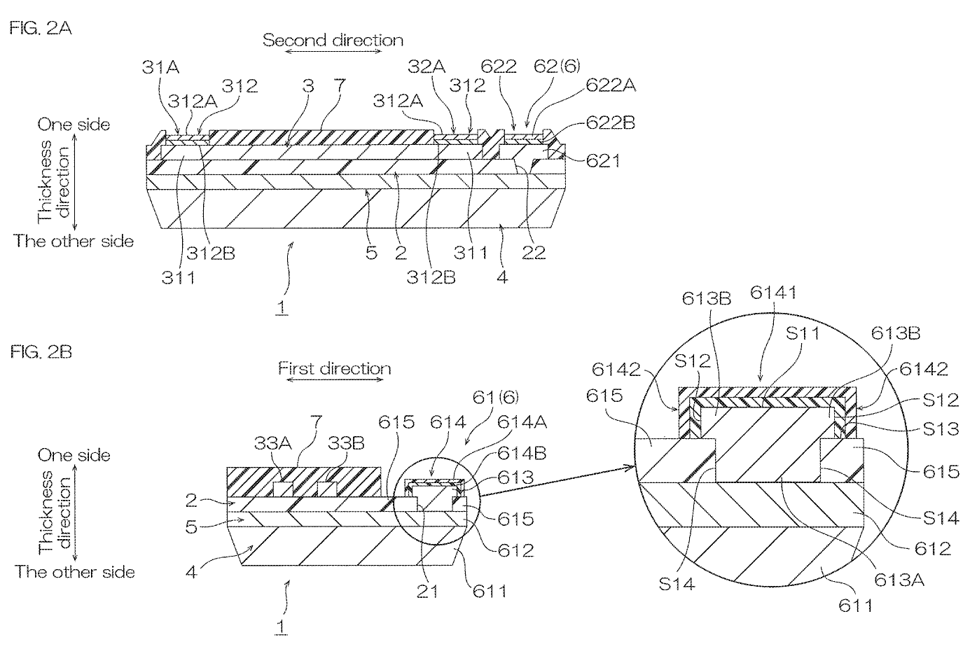

As shown in FIGS. 2A and 2B, the wiring circuit board 1 includes a first insulating layer 2 as an example of an insulating layer, a first circuit pattern 3 (see FIG. 1), a metal support layer 4, a conductor layer 5, a second circuit pattern 6 (see FIG. 1), and a second insulating layer 7.

### (1) First Insulating Layer

The first insulating layer 2 insulates the metal support layer 4 and the conductor layer 5 from the first circuit pattern 3. The first insulating layer 2 is made of resin. Examples of the resin include polyimide, maleimide, epoxy resin, polybenzoxazole, and polyester. The first insulating layer 2 has a through hole 22.

### (2) First Circuit Pattern

The first circuit pattern 3 is disposed at one side of the first insulating layer 2 in a thickness direction of the first insulating layer 2. The thickness direction is perpendicular to the first direction and the second direction. The first circuit pattern 3 is disposed on a one-side surface of the first insulating layer 2 in the thickness direction.

As shown in FIG. 1, the first circuit pattern 3 includes a plurality of terminals 31A and 31B, a plurality of terminals 32A and 32B, and a plurality of wires 33A and 33B. The terminals 31A and 31B are aligned in the first direction. The terminal 31B is disposed away from the terminal 31A in the first direction. Each of the terminal 31A and terminal 31B extends in the first direction and the second direction. Each of the terminals 31A and 31B has a substantially rectangular shape.

As shown in FIG. 2A, the terminal 31A includes a conductor layer 311. Although not shown, the terminal 31B includes a conductor layer 311. Each of the terminals 31A and 31B, if required, may have a covering layer 312.

The conductor layer 311 is disposed on the one-side surface of the first insulating layer 2 in the thickness direction. The conductor layer 311 is made of metal. Examples of the metal include copper, silver, gold, iron, aluminum, chromium, and an alloy thereof. From the viewpoint of obtaining good electrical properties, the conductor layer 311 is preferably made of copper.

Between the conductor layer 311 and the second insulating layer 7, preferably, a protective metal layer that protects the conductor layer 311 is disposed. The protective metal layer is made of metal. Examples of the material for the protective metal layer include chromium, nickel, titanium, and an alloy thereof.

The protective metal layer is not shown.

The covering layer 312 covers a surface of the conductor layer 311. In the present embodiment, the covering layer 312 covers a central portion of a one-side surface of the conductor layer 311 in the thickness direction (a portion that is not covered by the second insulating layer 7). The covering layer 312 has a surface layer 312A. The surface layer 312Ais made of a metal different from the conductor layer 311. The surface layer 312A is made, for example, of gold. The covering layer 312 preferably has an intermediate layer 312B. The covering layer 312 may not have an intermediate layer 312B. The intermediate layer 312B is disposed between the conductor layer 311 and the surface layer 312A. The intermediate layer 312B is made of a metal different from the conductor layer 311 and the surface layer 312A. The intermediate layer 312B is made, for example, of nickel.

As shown in FIG. 1, the terminal 32A is disposed away from the terminal 31A in the second direction. The terminal 32B is disposed away from the terminal 31B in the second direction. The terminals 32A and 32B are aligned in the first direction. The terminal 32B is disposed away from the terminal 32A in the first direction. Each of the terminals 32A and 32B, for example, has a substantially rectangular shape. The descriptions of the terminals 32A and 32B are the same as those of the terminals 31A and 31B. Therefore, the descriptions of the terminals 32A and 32B are omitted.

The wire 33A electrically connects the terminal 31 A and the terminal 32 A. One end of the wire 33A is connected to the terminal 31A. Specifically, one end of the wire 33A is connected to the conductor layer 311 of the terminal 31A (see FIG. 2A). The other end of the wire 33A is connected to the terminal 32A. Specifically, the other end of the wire 33A is connected to the conductor layer 311 of the terminal 32A (see FIG. 2A).

The wire 33B electrically connects the terminal 31B and the terminal 32B. One end of the wire 33B is connected to the terminal 31B. The other end of the wire 33 B is connected to the terminal 32 B.

The wires 33A and 33B are made of the same material as the conductor layer 311.

### (3) Metal Support Layer

As shown in FIGS. 2A and 2B, the metal support layer 4 is disposed at the other side of the first insulating layer 2 in the thickness direction. The metal support layer 4 is disposed at the opposite side to the first circuit pattern 3 with respect to the first insulating layer 2 in the thickness direction. The metal support layer 4 is insulated from the first circuit pattern 3 by the first insulating layer 2. The metal support layer 4 supports the first circuit pattern 3 and the first insulating layer 2. The entire metal support layer 4 overlaps the first insulating layer 2 in the thickness direction. Examples of the material for the metal support layer 4 include stainless steel and a copper alloy.

### (4) Conductor Layer

The conductor layer 5 is disposed at the other side of the first insulating layer 2 and one side of the metal support layer 4 in the thickness direction. In other words, the conductor layer 5 is disposed between the first insulating layer 2 and the metal support layer 4 in the thickness direction. The conductor layer 5 is in contact with an other-side surface of the first insulating layer 2 and in contact with a one-side surface of the metal support layer 4 in the thickness direction. The conductor layer 5 is disposed at the opposite side to the first circuit pattern 3 with respect to the first insulating layer 2 in the thickness direction. The conductor layer 5 is insulated from the first circuit pattern 3 by the first insulating layer 2. As shown in FIG. 2A, the conductor layer 5 extends from one end to the other end of the metal support layer 4 in the second direction, and, as shown in FIG. 2B, extends from one end to the other end of the metal support layer 4 in the first direction. The conductor layer 5 does not have a wiring pattern. The entire conductor layer 5 overlaps the first insulating layer 2 in the thickness direction. The conductor layer 5 overlaps the entire first circuit pattern 3 in the thickness direction. The conductivity of the conductor layer 5 is higher than the conductivity of the metal support layer 4. The conductor layer 5 is made, for example, of copper.

Between the metal support layer 4 and the conductor layer 5, a joint layer that joins the metal support layer 4 and the conductor layer 5 may be disposed. The joint layer is made of metal. Examples of the material for the joint layer include chromium, nickel, titanium, and an alloy thereof.

Further, between the conductor layer 5 and the first insulating layer 2, preferably, a protective metal layer that protects the conductor layer 5 is disposed. The protective metal layer is made of metal. Examples of the material for the protective metal layer include chromium, nickel, titanium, and an alloy thereof.

The joint layer and the protective metal layer are not shown.

### (5) Second Circuit Pattern

As shown in FIG. 1, the second circuit pattern 6 is independent from the first circuit pattern 3. The second circuit pattern 6 includes a first terminal 61 and a second terminal 62. The first terminal 61 and the second terminal 62 are electrically connected through the conductor layer 5 (see FIGS. 2A and 2B), and thus the second circuit pattern 6 functions as an electrical circuit independent from the first circuit pattern 3.

### (5-1) First Terminal

In the present embodiment, the first terminal 61 is disposed between the terminal 31B and the terminal 32B in the second direction. In other words, the first terminal 61 is aligned with the wires 33A and 33B in the first direction. The first terminal 61 is disposed at the opposite side to the wire 33A with respect to the wire 33B in the first direction. The first terminal 61 has a prismatic shape extending in the first direction. The position and shape of the first terminal 61 are not limited to the present embodiment.

The first terminal 61 does not overlap the first insulating layer 2 in the thickness direction. The first terminal 61 does not overlap the second insulating layer 7 in the thickness direction, either.

As shown in FIG. 2B, the first terminal 61 is continuous with the metal support layers 4. Therefore, the first terminal 61 is electrically connected to the metal support layer 4.

The first terminal 61 includes a metal layer 611, a terminal conductor layer 612, a terminal metal layer 613, a terminal covering layer 614, and an adhesion layer 615.

The metal layer 611 is continuous with the metal support layer 4. The metal layer 611 forms a single layer with the metal support layer 4. The metal layer 611 is made of the same material as the metal support layer 4. In the present embodiment, the metal layer 611 extends from the end portion of the metal support layer 4 at the opposite side to the wire 33A with respect to the wire 33B toward the opposite side to the wire 33A with respect to the wire 33B in the first direction.

The terminal conductor layer 612 is disposed at one side of the metal layer 611 in the thickness direction. The terminal conductor layer 612 is disposed at a one-side surface of the metal layer 611 in the thickness direction. In the present embodiment, the terminal conductor layer 612 is disposed between the metal layer 611 and the terminal metal layer 613 in the thickness direction. In the present embodiment, the terminal conductor layer 612 includes the terminal metal layer 613 when being projected in the thickness direction, although the present invention is not limited to the embodiment. When being projected in the thickness direction, the terminal conductor layer 612 may overlap a portion of the terminal metal layer 613, and may include a portion which does not overlap the terminal metal layer 613.

The terminal conductor layer 612 is continuous with the conductor layer 5. The terminal conductor layer 612 forms a single layer with the conductor layer 5. The terminal conductor layer 612 is made of the same material as the conductor layer 5. In the present embodiment, the terminal conductor layer 612 extends from the end portion of the conductor layer 5 at the opposite side to the wire 33A with respect to the wire 33B toward the opposite side to the wire 33A with respect to the wire 33B in the first direction.

Between the metal layer 611 and the terminal conductor layer 612, a joint layer that joins the metal layer 611 and the terminal conductor layer 612 may be disposed. The joint layer is made of metal. Examples of the material for the joint layer include chromium, nickel, titanium, and an alloy thereof.

Furthermore, between the terminal conductor layer 612 and the terminal metal layer 613 and between the terminal conductor layer 612 and the adhesion layer 615, preferably, a protective metal layer that protects the terminal conductor layer 612 is disposed. The protective metal layer is made of metal. Examples of the material for the protective metal layer include chromium, nickel, titanium, and an alloy thereof.

The joint layer and the protective metal layer are not shown.

As shown in the enlarged view in FIG. 2B, the terminal metal layer 613 is disposed at one side of the metal layer 611 in the thickness direction. In the present embodiment, the terminal metal layer 613 is disposed at one side of the terminal conductor layer 612 in the thickness direction. The terminal metal layer 613 is disposed at a one-side surface of the terminal conductor layer 612 in the thickness direction. The terminal metal layer 613 is in contact with the terminal conductor layer 612. In other words, the terminal metal layer 613 is electrically connected to the terminal conductor layer 612. More specifically, the terminal metal layer 613 is electrically connected to the terminal conductor layer 612 through an opening portion 21 of the adhesion layer 615 described later.

The terminal metal layer 613 includes a central portion 613A and a peripheral edge portion 613B. In the present embodiment, the central portion 613A is disposed on the one-side surface of the terminal conductor layer 612 in the thickness direction.

The central portion 613A is in contact with the terminal conductor layer 612. In more detail, the central portion 613A is disposed in the opening portion 21 of the adhesion layer 615 described later, and is electrically connected to the terminal conductor layer 612. A side surface S14 of the central portion 613A of the terminal metal layer 613 is in contact with an inner peripheral surface of the adhesion layer 615 facing the opening portion 21. The peripheral edge portion 613B is disposed on a one-side surface S13 of the adhesion layer 615 in the thickness direction. The peripheral edge portion 613B is in contact with the one-side surface S13 of the adhesion layer 615.

The terminal metal layer 613 is made of metal. Examples of the metal include copper, silver, gold, iron, aluminum, chromium, and an alloy thereof. From the viewpoint of obtaining good electrical properties, the terminal metal layer 613 is preferably made of copper.

As shown in the enlarged view in FIG. 2B, the terminal covering layer 614 covers the terminal metal layer 613. In the present embodiment, the terminal covering layer 614 includes a first portion 6141 that covers the one-side surface S11 of the terminal metal layer 613 in the thickness direction and a second portion 6142 that covers the side surface S12 of the peripheral edge portion 613B of the terminal metal layer 613. The first portion 6141 covers the entire one-side surface S11 of the terminal metal layer 613 in the thickness direction. Furthermore, the second portion 6142 covers the entire side surface S12 of the peripheral edge portion 613B of the terminal metal layer 613.

The terminal covering layer 614 is in contact with the one-side surface S13 of the adhesion layer 615 in the thickness direction. In more detail, the second portion 6142 is in contact with the one-side surface S13 of the adhesion layer 615 in the thickness direction.

As shown in FIG. 2B, the terminal covering layer 614 includes a surface layer 614A. The terminal covering layer 614 includes an intermediate layer 614B. The terminal covering layer 614 may not include an intermediate layer 614B. The intermediate layer 614B is disposed between the terminal metal layer 613 and the surface layer 614A. The surface layer 614A is made of a metal different from the metal layer 611, the terminal conductor layer 612, and the terminal metal layer 613. The surface layer 614A is made, for example, of gold. The intermediate layer 614B is made of a metal different from the metal layer 611, the terminal conductor layer 612, the terminal metal layer 613, and the surface layer 614A. The intermediate layer 614B is made, for example, of nickel. That is, the terminal covering layer 614 is made of a metal.

In the present embodiment, as shown in FIG. 1, the adhesion layer 615 is disposed on the peripheral edge portion 613B of the terminal metal layer 613. In more detail, the adhesion layer 615 is disposed on the entire peripheral edge portion 613B of the terminal metal layer 613.

The adhesion layer 615 is disposed between the metal layer 611 and the terminal covering layer 614 in the thickness direction. In more detail, the adhesion layer 615 is disposed between the metal layer 611 and the second portion 6142 in the thickness direction. In the present embodiment, the adhesion layer 615 is disposed between the terminal conductor layer 612 and the terminal covering layer 614 in the thickness direction. In more detail, the adhesion layer 615 is disposed between the terminal conductor layer 612 and the second portion 6142 in the thickness direction. Furthermore, the adhesion layer 615 is also disposed between the terminal conductor layer 612 and the terminal metal layer 613 in the thickness direction. In more detail, the adhesion layer 615 is disposed between the terminal conductor layer 612 and the peripheral edge portion 613B of the terminal metal layer 613 in the thickness direction.

The adhesion layer 615 is disposed at one side of the metal layer 611 in the thickness direction. The one-side surface S13 of the adhesion layer 615 is in contact with the terminal metal layer 613. In more detail, the one-side surface S13 of the adhesion layer 615 is in contact with the peripheral edge portion 613B in the thickness direction.

Furthermore, the one-side surface S13 of the adhesion layer 615 is in contact with the terminal covering layer 614. In more detail, the one-side surface S13 of the adhesion layer 615 is in contact with the second portion 6142 in the thickness direction.

Furthermore, in the present embodiment, the adhesion layer 615 is disposed on the one-side surface of the terminal conductor layer 612 in the thickness direction. The adhesion layer 615 is in contact with the one-side surface of the terminal conductor layer 612 in the thickness direction.

The adhesion layer 615 includes an opening portion 21. The number of the opening portions 21 is not especially limited. Furthermore, the shapes of the opening portions 21 are not especially limited. In the present embodiment, the adhesion layer 615 includes one opening portion 21. Furthermore, the opening portion 21 is substantially rectangular when viewed from the thickness direction. In detail, the opening portion 21 is a substantially square when viewed from the thickness direction. The opening portion 21 of the adhesion layer 615 is included in the terminal metal layer 613 when being projected in the thickness direction.

The ratio of the total area of the opening portion 21 with respect to the one-side surface of the terminal metal layer 613 in the thickness direction is, for example, 0.001 or more, preferably 0.01 or more, and, for example, 0.95 or less, preferably 0.7 or less. When the adhesion layer 615 includes a plurality of opening portions 21, the total area of the opening portion 21 is the sum of the areas of the opening portions 21.

In the present embodiment, the adhesion layer 615 has a substantially angular ring shape when viewed from the thickness direction. In other words, the adhesion layer 615 has a substantially angular ring shape in a plan view. In more detail, the adhesion layer 615 has a substantially rectangular ring shape when viewed from the thickness direction. The inner peripheral surface of the adhesion layer 615 facing the opening portion 21 is in contact with the side surface S14 of the central portion 613A of the terminal metal layer 613. The inner peripheral surface of the adhesion layer 615 facing the opening portion 21 is preferably in contact with the entire side surface S14 of the central portion 613A of the terminal metal layer 613.

In the present embodiment, the adhesion layer 615 is continuous with the first insulating layer 2. The adhesion layer 615 forms a single layer with the first insulating layer 2. The adhesion layer 615 is made of the same material as the first insulating layer 2. The thickness of the adhesion layer 615 may be the same as or different from the thickness of the first insulating layer 2. In the present embodiment, the adhesion layer 615 extends from the end portion of the first insulating layer 2 at the opposite side to the wire 33A with respect to the wire 33B toward the opposite side to the wire 33A with respect to the wire 33B in the first direction.

### (5-2) Second Terminal

As shown in FIG. 1, in the present embodiment, the second terminal 62 is disposed in the other end portion of the wiring circuit board 1 in the second direction. The second terminal 62 has a substantially rectangular shape. The position and shape of the second terminal 62 are not limited to the present embodiment.

As shown in 2A, the second terminal 62 is disposed at one side of the first insulating layer 2 in the thickness direction. The second terminal 62 is electrically connected to the conductor layer 5 through the through hole 22 of the first insulating layer 2.

The second terminal 62 has a conductor layer 621 in the same manner as the terminal 31A of the first circuit pattern 3.

The second terminal 62 may have a covering layer 622, if necessary.

The conductor layer 621 is disposed on the one-side surface of the first insulating layer 2 in the thickness direction. The conductor layer 621 is made of the same material as the terminal 31A of the first circuit pattern 3.

Between the conductor layer 621 and the second insulating layer 7, preferably a protective metal layer that protects the conductor layer 621 is disposed. The protective metal layer is made of metal. Examples of the material for the protective metal layer include chromium, nickel, titanium, and an alloy thereof.

The protective metal layer is not shown.

The covering layer 622 covers the surface of the conductor layer 621. In the present embodiment, the covering layer 622 covers a central portion of a one-side surface of the conductor layer 621 in the thickness direction (a portion that is not covered by the second insulating layer 7). The covering layer 622 has a surface layer 622A. The surface layer 622A is made, for example, of gold. The covering layer 622 preferably has an intermediate layer 622B. The covering layer 622 may not have an intermediate layer 622B. The intermediate layer 622B is disposed between the conductor layer 621 and the surface layer 622A. The intermediate layer 622B is made, for example, of nickel.

### (6) Secondary Insulating Layer

The second insulating layer 7 is disposed at one side of the first insulating layer 2 in the thickness direction. The second insulating layer 7 is disposed on the one-side surface of the first insulating layer 2 in the thickness direction. The second insulating layer 7 is made of resin. Examples of the resin include polyimide, maleimide, epoxy resin, polybenzoxazole, and polyester. The second insulating layer 7 covers at least a portion of the first circuit pattern 3. The second insulating layer 7 covers the wires 33A and 33B (see FIG. 1). The second insulating layer 7 may cover the peripheral edge portion of each of the terminals 31A, 31B, 32A, 32B and the second terminal 62. The second insulating layer 7 does not cover the central portion of each of the terminals 31A, 31B, 32A, 32B and the second terminal 62.

### 2. Method of Producing Wiring Circuit Board

Next, a method of producing the wiring circuit board 1 is described.

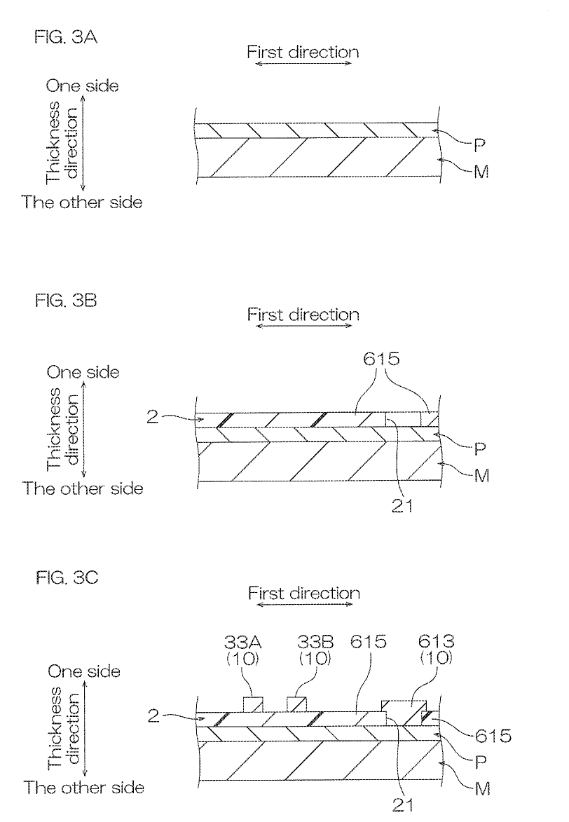

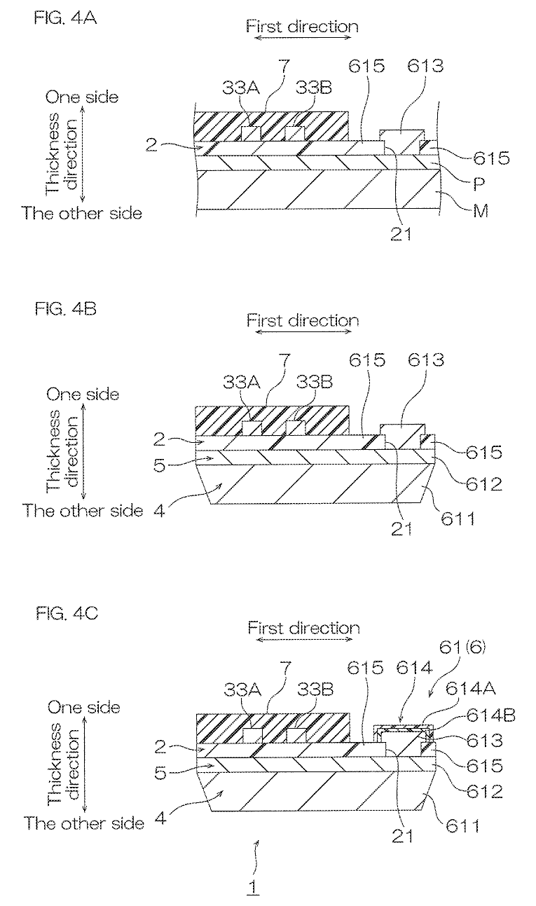

The method of producing the wiring circuit board 1 includes a conductor layer forming step (see FIG. 3A), a first insulating layer forming step (see FIG. 3B), a conductor pattern forming step (see FIG. 3C), a second insulating layer forming step (see FIG. 4A), an outer shape trimming step (see FIG. 4B), and a covering layer forming step (see FIG. 4C).

### (1) Conductor Layer Forming Step

As shown in FIG. 3A, in the conductor layer forming step, a conductor layer P is formed on the entire surface of a metallic substrate M, for example, by electrolytic plating.

In detail, first, in the thickness direction, the above-described joint layer is formed on a one-side surface of the substrate M. The joint layer is formed, for example, by sputtering.

Next, a conductor layer P is formed on the joint layer, for example, by electrolytic plating.

When a joint layer is not formed, a conductor layer P is formed on the one-side surface of the substrate M, for example, by electrolytic plating.

### (2) First Insulating Layer Forming Step

Next, as shown in FIG. 3B, in the first insulating layer forming step, a first insulating layer 2 and an adhesion layer 615 are formed on a one-side surface of the conductor layer P.

In detail, in the first insulating layer forming step, first, the above-described protective metal layer is formed on the one-side surface of the conductor layer P in the thickness direction. The protective metal layer is formed, for example, by sputtering.

Next, a solution (varnish) of a photosensitive resin is applied onto the conductor layer P and dried to form a coating film of the photosensitive resin. Next, the coating film of the photosensitive resin is exposed to light and developed. Thus, a first insulating layer 2 and an adhesion layer 615 are obtained.

In detail, after the coating film of the photosensitive resin is formed on the conductor layer P, a portion where the first insulating layer 2 and the adhesion layer 615 are not formed is shielded, for example, by a photomask. Thereafter, when the development is carried out, the light-shielded portion of the coating film of the photosensitive resin is removed, and thus the first insulating layer 2 or the adhesion layer 615 is not formed.

In the thickness direction, the first insulating layer 2 and the adhesion layer 615 are not formed at least in a portion of the one-side surface of the conductor layer P. Specifically, as shown in FIG. 3B, in the thickness direction, the adhesion layer 615 is not formed on the one-side surface of the conductor layer P at a position where an opening portion 21 is to be formed. In other words, in the thickness direction, the coating film of the photosensitive resin is removed on the one-side surface of the conductor layer P at a position where an opening portion 21 is to be formed. By that, an opening portion 21 is formed.

Further, although not shown, the coating film of the photosensitive resin is also removed at a position where a through hole 22 is to be formed. By that, a through hole 22 is formed.

### (3) Conductive Pattern Forming Step

Next, as shown in FIG. 3C, in the conductor pattern forming step, a conductor pattern 10 is formed on the first insulating layer 2. The conductor pattern 10 includes the conductor layer 311 of each of the terminals 31A, 31B, 32A, 32B, the wires 33A and 33B, the terminal metal layer 613 of the first terminal 61, and the conductor layer 621 of the second terminal 62.

In detail, first, in the thickness direction, a seed layer is formed on a one-side surface of the first insulating layer 2, on a one-side surface of the adhesion layer 615, and on the one-side surface of the conductor layer P. The seed layer is formed, for example, by sputtering. Examples of the material for the seed layer include chromium, copper, nickel, titanium, and an alloy thereof.

Next, the seed layer is covered with a plating resist.

Next, the plating resist is exposed to light and developed. Then, the plating resist of the portion where a conductor pattern 10 is to be formed is removed, and the seed layer is exposed in the portion where a conductor pattern 10 is to be formed. On the other hand, the plating resist of the portion where a conductive pattern 10 is not formed remains.

Next, a conductive pattern 10 is formed on the exposed seed layer by electrolytic plating. After the electrolytic plating is completed, the plating resist is released, and the seed layer exposed due to the release of the plating resist is removed by etching.

Thus, a conductor pattern 10 is formed on the first insulating layer 2.

### (4) Second Insulating Layer Forming Step

Next, as shown in FIG. 4A, in the second insulating layer forming step, a second insulating layer 7 is formed on the first insulating layer 2.

In detail, in the second insulating layer forming step, first, the above-described protective metal layer is formed on the exposed surface of the conducting pattern 10 in the thickness direction. The protective metal layer is formed, for example, by electroless plating.

Next, a solution (varnish) of the photosensitive resin is applied on the conductor pattern 10, the first insulating layer 2, and the conductor layer P, and dried to form a coating film of the photosensitive resin.

Next, the coating film of the photosensitive resin is exposed to light and developed. Thus, a second insulating layer 7 is formed on the first insulating layer 2.

In detail, after the coating film of the photosensitive resin is formed on the conducting pattern 10 and the first insulating layer 2, a portion where the second insulating layer 7 is not formed is shielded, for example, by a photomask. Thereafter, when the development is carried out, the light-shielded portion of the coating film of the photosensitive resin is removed, and thus the second insulating layer 7 is not formed thereon.

### (5) Outer Shape Trimming Step

Next, as shown in FIG. 4B, in the outer shape trimming step, the substrate M and the conductor layer P are etched to form a metal support layer 4, a conductor layer 5, a metal layer 611, and a terminal conductor layer 612.

### (6) Covering Layer Forming Step

Next, as shown in FIG. 4C, in the covering layer forming step, for example, electroless nickel plating and electroless gold plating are carried out in order to simultaneously form a covering layer 312, a covering layer 622, and a terminal covering layer 614. The covering layer 312, the covering layer 622, and the terminal covering layer 614 may be formed by electroplating.

As described above, the above-described wiring circuit board 1 is obtained.

### 3. Operations and Effects

(1) According to the wiring circuit board 1, as shown in FIGS. 1 and 2A, the first terminal 61 of the second circuit pattern 6 includes the metal layer 611 continuous with the metal support layer 4.

Therefore, by utilizing the metal support layer 4 supporting the first circuit pattern 3, it is possible to design the second circuit pattern 6 independent from the first circuit pattern 3.

As a result, it is possible to improve the degree of freedom of the circuit design.

Further, the metal layer 611 of the first terminal 61 is continuous with the metal support layer 4, and thus it is possible to suppress the reduction in the stiffness of the metal support layer 4 due to the formation of the second circuit pattern 6, as compared with the case of forming the second circuit pattern 6 by separating a portion of the metal support layer 4 from the metal support layer 4.

Furthermore, the terminal covering layer 614 covers the terminal metal layer 613, and thus the terminal metal layer 613 can be protected by the terminal covering layer 614.

(2) According to the wiring circuit board 1, as shown in FIG. 2B, the first terminal 61 includes the adhesion layer 615 disposed between the metal layer 611 and the terminal covering layer 614.

Thus, it is possible to suppress the release of the terminal covering layer 614.

(3) According to the wiring circuit board 1, as shown in FIGS. 1 and 2B, the adhesion layer 615 is disposed in the peripheral edge portion 613B of the terminal metal layer 613.

Therefore, in the peripheral edge portion 613B of the terminal metal layer 613, it is possible to suppress the release of the terminal covering layer 614.

(4) As shown in FIG. 2A, the wiring circuit board 1 further includes the conductor layer 5 disposed between the first insulating layer 2 and the metal support layer 4 in the thickness direction.

Therefore, it is possible to improve the electrical properties of the wiring circuit board 1.

(5) According to the wiring circuit board 1, as shown in FIG. 2B, the first terminal 61 further includes the terminal conductor layer 612 disposed between the metal layer 611 and the terminal metal layer 613 in the thickness direction.

Thus, it is possible to improve the conductive performance of the second circuit pattern 6.

(6) According to the wiring circuit board 1, as shown in FIG. 2B, the terminal conductor layer 612 is continuous with the conductor layer 5.

Therefore, by utilizing the conductor layer 5, it is possible to design the second circuit pattern 6 independent from the first circuit pattern 3.

As a result, it is possible to improve the degree of freedom of the circuit design.

### 4. Modified Examples

Modified examples are described. In the modified examples, the same members as in the above-described embodiment are denoted by the same reference numerals, and the descriptions thereof are omitted.

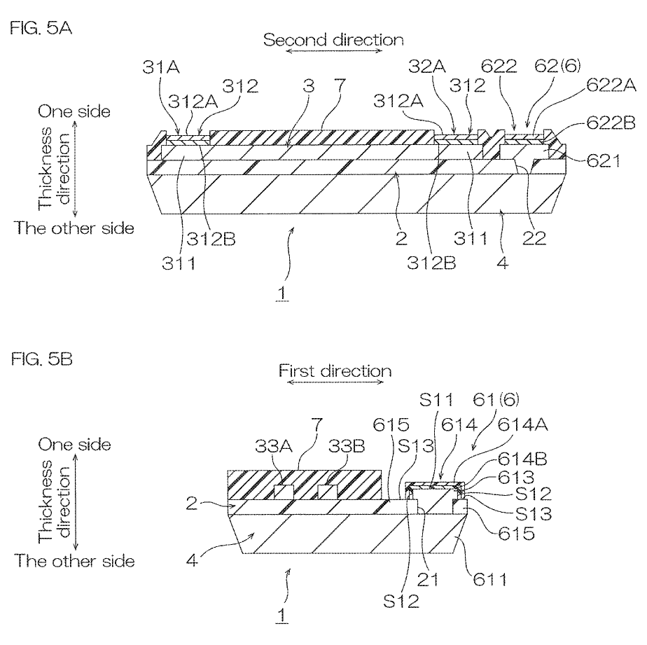

(1) As shown in FIG. 5A, the wiring circuit board 1 may not have a conductor layer 5. In this case, the metal support layer 4 is in contact with the other-side surface of the first insulating layer 2 in the thickness direction.

Further, as shown in FIG. 5B, the first terminal 61 may not include a terminal conductor layer 612 while including a metal layer 611, a terminal metal layer 613, a terminal covering layer 614, and an adhesion layer 615.

The adhesion layer 615 is disposed between the metal layer 611 and the terminal covering layer 614 in the thickness direction. In more detail, the adhesion layer 615 is disposed between the metal layer 611 and the second portion 6142 in the thickness direction. Furthermore, the adhesion layer 615 is disposed also between the metal layer 611 and the terminal metal layer 613 in the thickness direction. In more detail, the adhesion layer 615 is disposed between the metal layer 611 and the peripheral edge portion 613B of the terminal metal layer 613 in the thickness direction.

The terminal metal layer 613 is disposed at one side of the metal layer 611 in the thickness direction. The terminal metal layer 613 is disposed on a one-side surface of the metal layer 611 in the thickness direction. The terminal metal layer 613 is in contact with the metal layer 611. In other words, the terminal metal layer 613 is electrically connected to the metal layer 611. In more detail, the terminal metal layer 613 is electrically connected to the metal layer 611 through the opening portion 21 of the adhesion layer 615.

The central portion 613A is disposed on the one-side surface of the metal layer 611 in the thickness direction. The central portion 613A is in contact with the metal layer 611. In more detail, the central portion 613A is disposed in the opening portion 21 of the adhesion layer 615, and is electrically connected to the metal layer 611.

As shown in FIG. 5A, the second terminal 62 is electrically connected to the metal support layer 4 through the through hole 22 of the first insulating layer 2.

Thus, the first terminal 61 and the second terminal 62 can be electrically connected through the metal support layer 4.

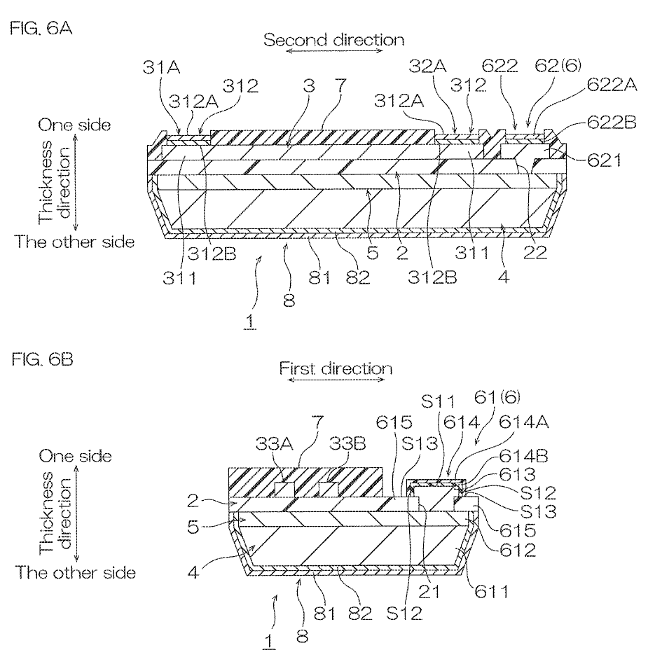

(2) As shown in FIGS. 6A and 6B, the wiring circuit board 1 may have a covering layer 8.

The covering layer 8 covers the metal support layer 4. In detail, the covering layer 8 covers an entire other-side surface of the metal support layer 4 in the thickness direction. Furthermore, the covering layer 8 covers an entire end surface of the metal support layer 4 and an entire end surface of the conductor layer 5. In the present modified example, the end surface of the conductor layer 5 is continuous with the end surface of the metal support layer 4 in the thickness direction. The end surface of the conductor layer 5 is discontinuous with the end surface of the first insulating layer 2. Furthermore, the end surface of the conductor layer 5 is discontinuous with the end surface of the adhesion layer 615. The covering layer 8 includes a surface layer 81. The covering layer 8 preferably includes an intermediate layer 82. The covering layer 8 may not include an intermediate layer 82. The intermediate layer 82 is disposed between the metal support layer 4 and the surface layer 81 and between the conductor layer 5 and the surface layer 81. The covering layer 8 is made of metal. In detail, the surface layer 81 is made of a metal different from the metal support layer 4 and the conductor layer 5. The surface layer 81 is made, for example, of gold. The intermediate layer 82 is made of a metal different from the metal support layer 4, the conductor layer 5, and the surface layer 81. The intermediate layer 82 is made, for example, of nickel.

When the wiring circuit board 1 includes the covering layer 8, in the covering layer forming step, the covering layer 8, the covering layer 312, the covering layer 622, and the terminal covering layer 614 may be simultaneously formed.

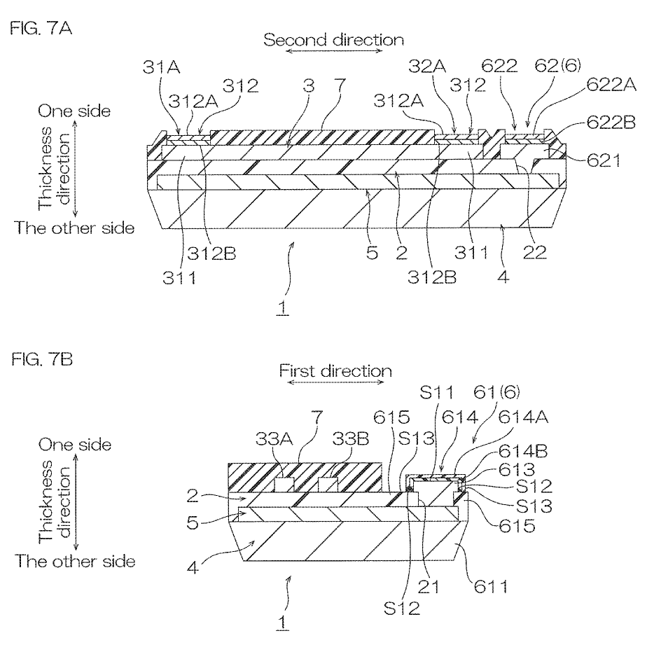

(3) As shown in FIGS. 7A and 7B, the end surface of the metal support layer 4 may be discontinuous with the end surface of the conductor layer 5, and the end surface of the metal layer 611 may be discontinuous with the end surface of the terminal conductor layer 612.

Specifically, as shown in FIG. 7A, the end surface of the conductor layer 5 may be disposed separately more inwardly than the end surface of the metal support layer 4 and covered by the first insulating layer 2. Further, as shown in FIG. 7B, the end surface of the terminal conductor layer 612 may be disposed separately more inwardly than the end surface of the metal layer 611 and covered by the adhesion layer 615.

When the wiring circuit board 1 of this modified example is produced, in the conductor layer forming step, after a plating resist is formed in a portion where the conductor layer 5 or the terminal conductor layer 612 is not formed, a conductor layer P is formed by electrolytic plating. Thereafter, the plating resist is removed. When a joint layer is formed on the substrate M, the joint layer of the portion where the plating resist is removed is also removed.

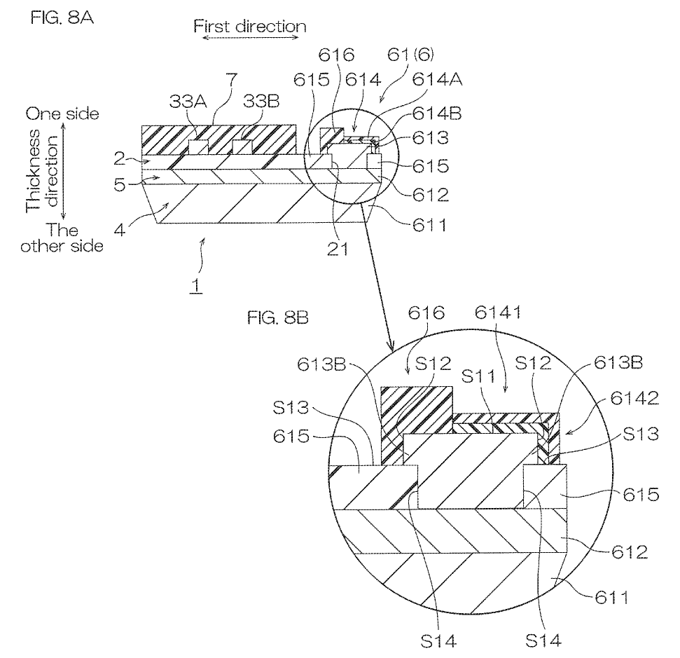

(4) As shown in FIGS. 8A and 8B, the first terminal 61 may include a terminal insulating layer 616. That is, the first terminal 61 may include a metal layer 611, a terminal conductor layer 612, a terminal metal layer 613, a terminal covering layer 614, an adhesion layer 615, and a terminal insulating layer 616.

The terminal covering layer 614 includes a first portion 6141 that covers a portion of the one-side surface S11 of the terminal metal layer 613 in the thickness direction and a second portion 6142 that covers a portion of the side surface S12 of the peripheral edge portion 613B of the terminal metal layer 613. In the present modified example, the end surface of the terminal covering layer 614 other than the portion in contact with the adhesion layer 615 is in contact with the terminal insulating layer 616.

In the thickness direction, the adhesion layer 615 is disposed between the terminal conductor layer 612 and the second portion 6142 of the terminal covering layer 614, and also disposed between the terminal conductor layer 612 and the terminal insulating layer 616.

In the thickness direction, the one-side surface S13 of the adhesion layer 615 is in contact with the second portion 6142 and the terminal insulating layer 616.

The terminal insulating layer 616 includes a portion that covers a portion of the one-side surface S11 of the terminal metal layer 613 in the thickness direction, and a portion that covers a portion of the side surface S12 of the peripheral edge portion 613B of the terminal metal layer 613. In more detail, the terminal insulating layer 616 covers the rest of the terminal metal layer 613 in the thickness direction. The rest of the terminal metal layer 613 is a portion other than the portion covered by the terminal covering layer 614 on the one-side surface S11 of the terminal metal layer 613. Furthermore, the terminal insulating layer 616 covers the rest of the peripheral edge portion 613B of the terminal metal layer 613. The rest of the peripheral edge portion 613B of the terminal metal layer 613 is a portion other than the portion covered by the terminal covering layer 614 on the side surface S12 of the peripheral edge portion 613B of the terminal metal layer 613.

The terminal insulating layer 616 is made of resin. Examples of the resin include polyimide, maleimide, epoxy resin, polybenzoxazole, and polyester.

Between the terminal metal layer 613 and the terminal insulating layer 616, preferably, a protective metal layer that protects the terminal metal layer 613 is disposed. The protective metal layer is made of metal. Examples of the material for the protective metal layer include chromium, nickel, titanium, and an alloy thereof.

The protective metal layer is not shown.

When the first terminal 61 includes the terminal insulating layer 616, in the second insulating layer forming step, the second insulating layer 7 and the terminal insulating layer 616 are simultaneously formed.

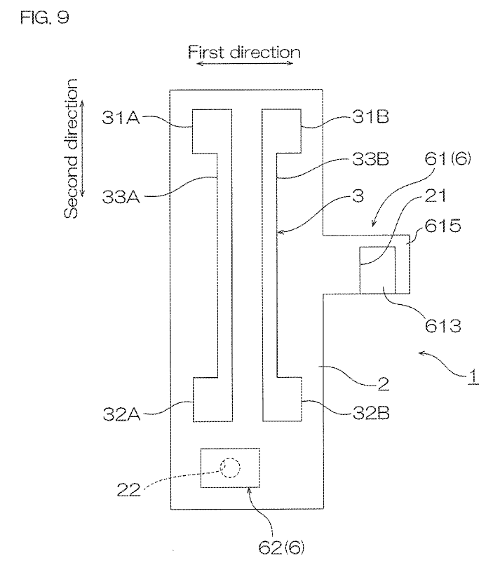

(5) As shown in FIG. 9, the adhesion layer 615 may be disposed in a portion of the peripheral edge portion 613B of the terminal metal layer 613.

The adhesion layer 615 has a substantially U-shape when viewed from the thickness direction. In other words, the adhesion layer 615 has a substantially U-shape in a plan view.

The end surface of the terminal metal layer 613 exposed from the adhesion layer 615 (in FIG. 9, the end surface of the terminal metal layer 613 on the terminals 32A and 32B side in the second direction) is covered by the terminal covering layer 614.

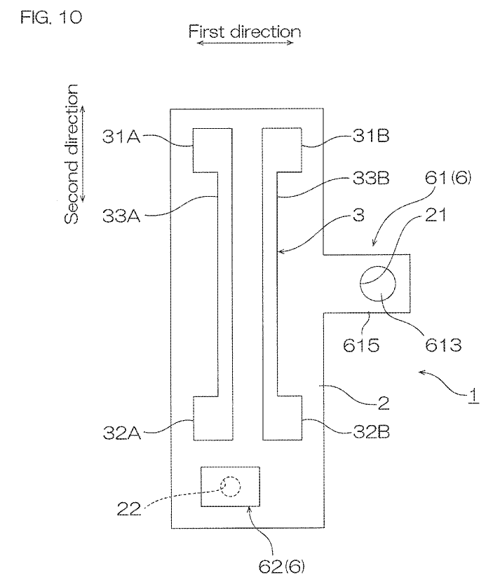

(6) As shown in FIG. 10, the opening portion 21 may have a substantially circular shape when viewed from the thickness direction. In other words, the opening portion 21 may have a substantially circular shape in a plan view.

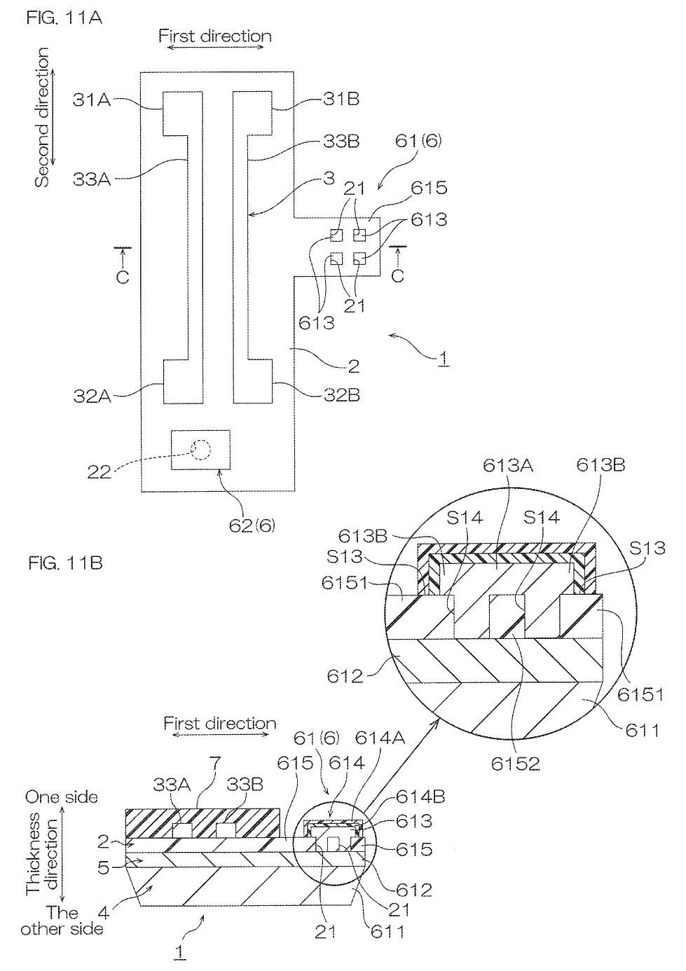

(7) As shown in FIGS. 11A and 11B, the adhesion layer 615 may include a plurality of opening portions 21. In the present modified example, the adhesion layer 615 includes four opening portions 21.

In the present modified example, the central portion 613A is disposed in each of the plurality of opening portions 21 of the adhesion layer 615, and electrically connected to the terminal conductor layer 612. The side surfaces S14 of the central portion 613A of the terminal metal layer 613 are in contact with the inner peripheral surfaces of the adhesion layer 615 facing the plurality of opening portions 21, respectively. Furthermore, the central portion 613A is also in contact with a one-side surface of an internal portion 6152 (described below) of the adhesion layer 615 in the thickness direction.

The terminal covering layer 614 is in contact with the one-side surface S13 of the adhesion layer 615 in the thickness direction. In more detail, in the thickness direction, the terminal covering layer 614 is in contact with the one-side surface S13 of an external portion 6151 (described below) of the adhesion layer 615.

In the present modified example, the adhesion layer 615 is disposed in a portion of the central portion 613A of the terminal metal layer 613 and on the peripheral edge portion 613B of the terminal metal layer 613. In more detail, in the thickness direction, the adhesion layer 615 includes the external portion 6151 disposed between the terminal conductor layer 612 and the second portion 6142 and the internal portion 6152 disposed between the terminal conductor layer 612 and the central portion 613A.

In the thickness direction, the one-side surface S13 of the external portion 6151 is in contact with the second portion 6142, and the one-side surface of the internal portion 6152 is in contact with the central portion 613A.

In the present modified example, the adhesion layer 615 has a lattice shape when viewed from the thickness direction. In more detail, the external portion 6151 has a substantially angular ring shape when viewed from the thickness direction. The internal portion 6152 is continuous with the external portion 6151 and has a substantially cross shape when viewed from the thickness direction.

(8) Also in the above-described modified examples (1) to (7), it is possible to improve the degree of freedom of the circuit design in the same manner as in the above-described embodiment.

While the illustrative embodiments of the present invention are provided in the above-described description, such is for illustrative purpose only and it is not to be construed as limiting the scope of the present invention. Modification and variation of the present invention that will be obvious to those skilled in the art is to be covered by the following claims.

### Industrial Applicability

The wiring circuit board of the present invention can be used for connecting electronic components.

### DESCRIPTION OF REFERENCE NUMERALS

1 Wiring circuit board
2 First insulating layer
3 First circuit pattern
4 Metal support layer
5 Conductor layer
6 Second circuit pattern
61 First terminal
62 Second terminal
611 Metal layer
612 Terminal conductor layer
613 Terminal metal layer
614 Terminal covering layer
615 Adhesion layer

1. A wiring circuit board comprising:
a first insulating layer;
a first circuit pattern disposed at one side of the first insulating layer in a thickness direction of the first insulating layer;
a metal support layer disposed at an opposite side to the first circuit pattern with respect to the first insulating layer in the thickness direction, insulated from the first circuit pattern by the first insulating layer, and supporting the first circuit pattern and the first insulating layer; and
a second circuit pattern independent from the first circuit pattern,
wherein the second circuit pattern includes a first terminal,
wherein the first terminal includes:
a metal layer continuous with the metal support layer;
a terminal metal layer disposed at one side of the metal layer in the thickness direction;
a terminal covering layer made of metal and covering the terminal metal layer; and
an adhesion layer disposed between the metal layer and the terminal covering layer in the thickness direction.

2. The wiring circuit board according to claim 1,
wherein the adhesion layer is disposed in a peripheral edge portion of the terminal metal layer.

3. The wiring circuit board according to claim 1,
wherein in the thickness direction, the adhesion layer is disposed between the metal layer and the terminal metal layer,
wherein the adhesion layer includes an opening portion, and
wherein the terminal metal layer is electrically connected to the metal layer through the opening portion.

4. The wiring circuit board according to claim 1, further comprising
a conductor layer disposed between the first insulating layer and the metal support layer in the thickness direction.

5. The wiring circuit board according to claim 4,
wherein the first terminal further includes a terminal conductor layer disposed between the metal layer and the terminal metal layer in the thickness direction.

6. The wiring circuit board according to claim 5,
wherein the terminal conductor layer is continuous with the conductor layer.

7. The wiring circuit board according to claim 5,
wherein in the thickness direction, the adhesion layer is disposed between the terminal conductor layer and the terminal metal layer,
wherein the adhesion layer includes an opening portion, and
wherein the terminal metal layer is electrically connected to the terminal conductor layer through the opening portion.
